(19) United States
(12) Patent Application Publication
(10) Pub. No.: US 2005/0039937 A1
(43) Pub. Date: Feb. 24, 2005

(54) Method for making an electromagnetic radiation shielding fabric

(75) Inventors: Ya-Hui Yeh, Ping-Tung Hsien (TW); Cheng-Tao Wu, Kaohsiung City (TW); Lee-Cheng Chen, Tainan City (TW)

Correspondence Address: WEBB ZIESENHEIM LOGSDON ORKIN & HANSON, P.C.;700 Koppers Building, 436 Seventh Avenue, Pittsburgh, PA, 15219-1818, US

(73) Assignee: HELIX TECHNOLOGY, INC.

(21) Appl. No.: 10/792,421

(22) Filed: Mar. 3, 2004

(30) Foreign Application Priority Data
Aug. 18, 2003 (TW) 092122599

(51) Int. Cl. H05K 9/00

(52) U.S. Cl. 174/35 MS

(57) ABSTRACT

A method for making an electromagnetic radiation shielding fabric includes the steps of forming a radiation shielding metal layer on a fabric substrate through sputtering deposition techniques, and forming a protective metal layer on the radiation shielding metal layer. The radiation shielding metal layer is made from a first metal selected from the group consisting of copper and silver. The protective metal layer is made from a second metal selected from the group consisting of nickel, chromium, nickel-chromium alloy, and titanium. The aforesaid sputtering deposition is conducted at a power ranging from 300 to 1000 watts and a deposition time ranging from 17 to 90 seconds.

### CROSS-REFERENCE TO RELATED APPLICATION

This application claims priority of Taiwanese application No. 092122599, filed on Aug. 18, 2003.

### BACKGROUND OF THE INVENTION

1. Field of the Invention

This invention relates to a method for making an electromagnetic radiation shielding fabric using sputtering deposition techniques.

2. Description of the Related Art

Electromagnetic radiation shielding fabrics normally include a fabric substrate with two opposite side faces, two interfacial layers formed respectively on the side faces of the fabric substrate, two shielding layers formed respectively on the interfacial layers, and two protective layers formed respectively on the shielding layers. Each of the shielding layers is made from a metal, such as copper, aluminum, silver, and gold, that has high level shielding capability, which is proportional to the electrical conductivity thereof. It is noted that the metal for forming the shielding layers has poor coating capability on the fabric substrate. As a consequence, the interfacial layers are made from a metal having much higher adhesion to the fabric substrate than that of the shielding layers so as to serve as an adhering medium for adherence of the shielding layers to the fabric substrate. The protective layers are made from a metal resistant to oxidation so as to prevent the shielding layers from being oxidized.

Conventionally, the electromagnetic radiation shielding fabrics are made by plating techniques or by evaporation vapor deposition techniques. The evaporation vapor techniques are disadvantageous in that a relatively high temperature is required to vaporize the metal to be deposited, that the density of the thus formed deposited metal is loose, and that the surface of the thus formed deposited metal is rough.

### SUMMARY OF THE INVENTION

Therefore, the object of the present invention is to provide a method for making an electromagnetic radiation shielding fabric that is capable of overcoming the aforesaid drawbacks of the prior art.

According to the present invention, there is provided a method for making an electromagnetic radiation shielding fabric that has a radiation shielding effectiveness greater than 99.9% when exposed to a power frequency greater than 30 MHz. The method includes the steps of: forming a radiation shielding metal layer on a fabric substrate through sputtering deposition techniques; and forming a protective metal layer on the radiation shielding metal layer. The radiation shielding metal layer is made from a first metal selected from the group consisting of copper and silver. The protective metal layer is made from a second metal selected from the group consisting of nickel, chromium, nickel-chromium alloy, and titanium. The aforesaid sputtering deposition is conducted at a power ranging from 300 to 1000 watts and a deposition time ranging from 17 to 90 seconds.

### BRIEF DESCRIPTION OF THE DRAWINGS

In drawings which illustrate an embodiment of the invention,

FIGS. 1A to 1C are schematic fragmentary sectional views to illustrate consecutive steps of the preferred embodiment of a method of this invention for making an electromagnetic radiation shielding fabric; and

FIG. 2 is a schematic view to illustrate how a radiation shielding metal layer and a protective metal layer are deposited on a fabric substrate in a sputter according to the preferred embodiment of this invention.

### DETAILED DESCRIPTION OF THE PREFERRED EMBODIMENT

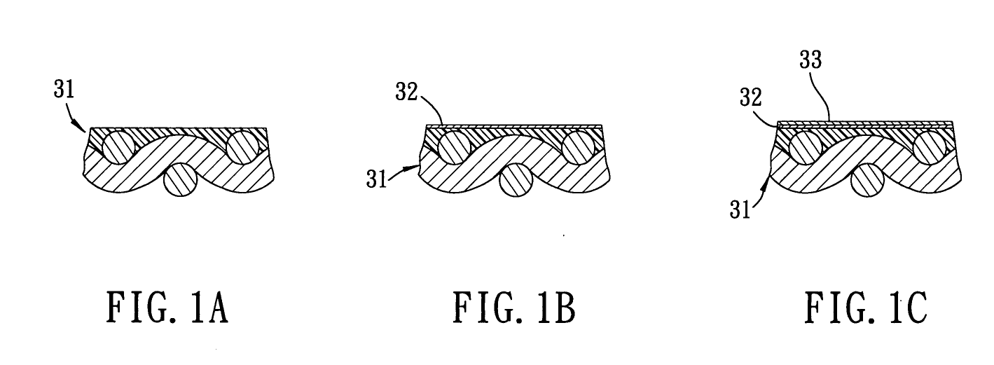

FIGS. 1A to 1C illustrate consecutive steps of the preferred embodiment of a method of this invention for making an electromagnetic radiation shielding fabric that includes a flexible fabric substrate 31, a radiation shielding metal layer 32 formed on the fabric substrate 31, and a protective metal layer 33 formed on the radiation shielding metal layer 32.

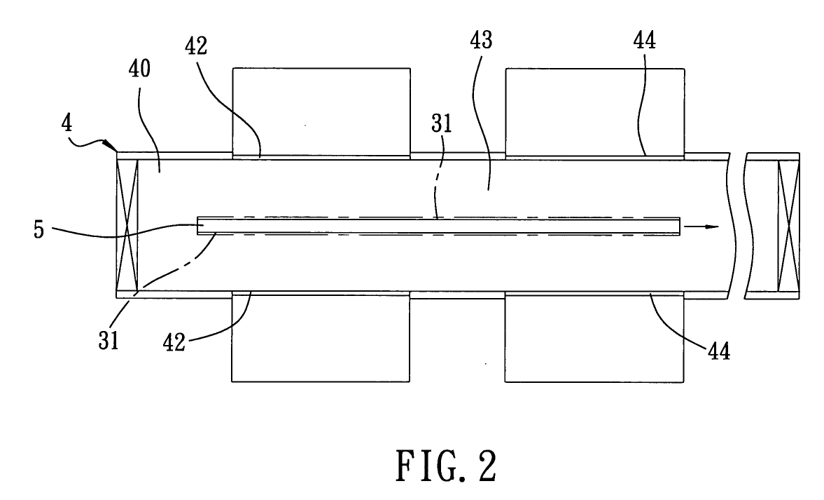

The method of this invention includes the steps of: placing the fabric substrate 31 on a carrier 5 and passing the carrier 5 into a vacuum depositing chamber 40 in a sputter 4 (see FIG. 2); forming the radiation shielding metal layer 32 on the fabric substrate 31 by passing the carrier 5 through two opposite first targets 42 mounted in the depositing chamber 40 (see FIG. 2); subsequently cooling the fabric substrate 31 by passing the same through a cooling zone 43 in the depositing chamber 40; and forming the protective metal layer 33 on the radiation shielding metal layer 32 by passing the carrier 5 through two opposite second targets 44 in the depositing chamber 40 (see FIG. 2). The radiation shielding metal layer 32 is made from a first metal selected from the group consisting of copper and silver. The protective metal layer 33 is made from a second metal selected from the group consisting of nickel, chromium, nickel-chromium alloy, and titanium. The aforesaid sputtering deposition for forming the radiation shielding metal layer 32 is conducted at a power ranging from 300 to 1000 watts, a deposition pressure ranging from 3×10⁻³ to 6×10⁻³ torr, and a deposition time ranging from 17 to 90 seconds. The aforesaid sputtering deposition for forming the protective metal layer 33 is conducted at a power ranging from 300 to 1000 watts, a deposition pressure ranging from 3×10⁻³ to 5.5×10⁻³ torr, and a deposition time ranging from 5 to 44 seconds. When the power is conducted at 300 W and the deposition time exceeds 90 seconds or when the power is conducted at 1000 W and the deposition time exceeds 17 seconds, the fabric sheet 31 may shrink or burn due to accumulated heat resulting from the sputtering operation. When the sputtering power is less than 300 W, the production rate is relatively inefficient, whereas when the sputtering power exceeds 1000 W, the fabric substrate 31 tends to shrink or burn.

In this embodiment, the fabric substrate 3 can be a woven (knitted or shuttled) or non-woven fabric. Preferably, the fabric substrate 3 is made from a plurality of synthetic fiber yarns having high tensile strength, high resistance to wearing, and high elastic modulus.

The present invention will now be described in greater detail with reference to the following Illustrative Examples 1 to 3.

Formation of the radiation shielding metal layer 32 and the protective metal layer 33 on the fabric substrate 31 for Examples 1 to 3 were carried out in the sputter 4 shown in FIG. 2. The carrier 5 together with the fabric substrate 31 traveled in the depositing chamber 40 at a constant speed for each Example. The depositing conditions (see Table 1) for forming the radiation shielding metal layer 32 for Examples 1 to 3 differed from each other. The depositing conditions for forming the protective metal layer 33 for Examples 1 to 3 were the same (i.e., deposition power: 450 W; speed: 5 mm/sec; deposition time: 17.6 seconds). The first and second targets 42, 44 used for forming the radiation shielding metal layer 32 and the protective metal layer 33 for Examples 1 to 3 were respectively copper and chromium.

TABLE 1

Depositing condition

| | | | Deposition | Deposition |
|---|---|---|---|---|
| | Power, | Speed, | time, | pressure, |
| Example | W | mm/sec | seconds | ×10⁻³ torr |
| 1 | 300 | 2 | 88.0 | 4.0 |
| 2 | 500 | 5 | 35.2 | 4.0 |
| 3 | 1000 | 10 | 17.6 | 4.0 |

The thickness of the thus formed radiation shielding metal layer 32 for Examples 1 to 3 are respectively 1355 Å, 910 Å, and 1010 Å. The thus formed electromagnetic radiation shielding fabrics for Examples 1 to 3 were subjected to a radiation shielding test. Table 2 shows the test results for Examples 1 to 3.

TABLE 2

| | EMI Shielding effect, db | | | | | | | | | |
|---|---|---|---|---|---|---|---|---|---|---|
| Example | 30 MHz | 101 MHz | 499 MHz | 900 MHz | 1200 MHz | 1500 MHz | 1800 MHz | 1901 MHz | 2451 MHz | 3000 MHz |
| 1 | 32.52 | 33.93 | 42.43 | 41.88 | 42.92 | 41.31 | 41.88 | 42.97 | 44.36 | 44.82 |
| 2 | 40.16 | 39.08 | 39.03 | 38.44 | 38.83 | 39.04 | 41.3 | 41.38 | 40.67 | 39.16 |
| 3 | 29.37 | 31.89 | 39.99 | 38.24 | 39.31 | 38.45 | 39.64 | 39.6 | 40.39 | 40.34 |

Table 3 shows the shielding effectiveness (%) corresponding to the db values of the test results.

TABLE 3

| db value | Shielding effectiveness, % | Shielding quality |
|---|---|---|
| 0-10 | 90 | very poor |
| 10-30 | 90-99.9 | below average |
| 30-60 | 99.9-99.9999 | average |
| 60-90 | 99.9999-99.9999999 | above average |
| 90-120 | 99.9999999-99.9999999999 | excellent |

By virtue of the sputtering techniques for forming the radiation shielding metal layer 32 of the electromagnetic radiation shielding fabric according to the method of this invention, the aforesaid drawbacks associated with the prior art can be eliminated.

With the invention thus explained, it is apparent that various modifications and variations can be made without departing from the spirit of the present invention.

1. A method for making an electromagnetic radiation shielding fabric that has a radiation shielding effectiveness greater than 99.9% when exposed to a power frequency greater than 30 MHz, the method comprising the steps of:
forming a radiation shielding metal layer on a fabric substrate through sputtering deposition techniques; and
forming a protective metal layer on the radiation shielding metal layer;
wherein the radiation shielding metal layer is made from a first metal selected from the group consisting of copper and silver;
wherein the protective metal layer is made from a second metal selected from the group consisting of nickel, chromium, nickel-chromium alloy, and titanium; and
wherein the aforesaid sputtering deposition is conducted at a power ranging from 300 to 1000 watts and a deposition time ranging from 17 to 90 seconds.

2. The method of claim 1, wherein the radiation shielding metal layer is made from copper.

3. The method of claim 2, wherein the fabric substrate is made from synthetic fibers.

4. The method of claim 3, wherein the sputtering deposition is carried out in a vacuum chamber in a sputter which is operated at a deposition pressure ranging from 3×10⁻³ to 6×10⁻³ torr.

5. The method of claim 4, further comprising cooling the fabric substrate after deposition of the first metal onto the fabric substrate and before deposition of the second metal onto the radiation shielding metal layer.
